(19) United States
(12) Patent Application Publication
(10) Pub. No.: US 2006/0033593 A1
(43) Pub. Date: Feb. 16, 2006

(54) Method and apparatus with improved varactor quality factor

(76) Inventors: Qinghua Kang, Newark, DE (US); Nicolaas Du Toit, Columbia, MD (US); Yongfei Zhu, Ellicott City, MD (US)

Correspondence Address: James S. Finn;C/O William Tucker, 14431 Goliad Dr., Box #8, Malakoff, TX, 75148, US

(21) Appl. No.: 11/198,965

(22) Filed: Aug. 8, 2005

Related U.S. Application Data
(60) Provisional application No. 60/601,566, filed on Aug. 13, 2004.

(51) Int. Cl. H03H 7/12

(52) U.S. Cl. 333/174

(57) ABSTRACT

An embodiment of the present invention provides an apparatus, comprising a varactor; and at least one external high-Q fixed capacitors combined with the varactor thereby improving the Q of the varactor. The at least one external high-Q fixed capacitor may combined in series with the varactor or in parallel with the varactor. Further, the varactor may be constructed of an internal low-tuning high-Q material with high-Q and large capacitance but low tuning range. The apparatus of one embodiment of the present invention may be incorporated into a 4-pole bandpass filter enabling Q improvement on the circuit performance or also may be incorporated into an amplifier or a voltage controlled oscillators or a phase shifters. Another embodiment of the present invention provides an apparatus, comprising a resonator and a varactor variably coupled into the resonator through an RF transformer, wherein by varying a coupling factor, the Q-factor and the tunability of the apparatus is capable of being affected.

### CROSS REFERENCE TO RELATED PATENT APPLICATION

This application claims the benefit of U.S. Provisional Patent Application No. 60/601,566, filed Aug. 13, 2004, entitled, “VOLTAGE TUNABLE CAPACITORS WITH IMPROVED QUALITY FACTOR.”

### BACKGROUND OF THE INVENTION

Quality factor (or Q) of a resonant circuit is proportional to the ratio of the average stored energy over the energy loss in the circuit. Thus it is a measure of the loss of a resonant circuit and lower loss implies higher Q. RF components with high Q are always desired in the design of radio devices and systems for RF, microwave and millimeter wave applications. For example, high-Q resonator or lumped-element components are desired to build high-Q filters, which capably possess preferable filter performance such as superior insertion loss and stop-band rejections. Thus, a strong need exists for a method and apparatus with improved varactor quality factor (Q).

### SUMMARY OF THE INVENTION

An embodiment of the present invention provides an apparatus, comprising a varactor and at least one external high-Q fixed capacitor combined with the varactor thereby improving the Q of the varactor. The at least one external high-Q fixed capacitor may be combined in series with the varactor or in parallel with the varactor. Further, the varactor may be constructed of an internal low-tuning high-Q material with high-Q and large capacitance but low tuning range.

The apparatus of one embodiment of the present invention may be incorporated into a 4-pole bandpass filter enabling Q improvement on the circuit performance or also may be incorporated into an amplifier or voltage controlled oscillators or phase shifters.

Another embodiment of the present invention provides an apparatus, comprising a resonator, and a varactor variably coupled into the resonator through an RF transformer, wherein by varying a coupling factor, the Q-factor and the tunability of the apparatus is capable of being affected.

Yet another embodiment of the present invention provides a method of improving the Q of a varactor, comprising combining at least one external high-Q fixed capacitor with the varactor thereby improving the Q of the varactor. This method may further comprise combining the at least one external high-Q fixed capacitor in series with the varactor or combining the at least one external high-Q fixed capacitor in parallel with the varactor. In an embodiment of the present invention this method may still further comprise constructing the varactors of an internal low-tuning high-Q material with high-Q and large capacitance but low tuning range and incorporating the at least one external high-Q fixed capacitor with the varactor into a 4-pole bandpass filter enabling Q improvement.

Yet another embodiment of the present invention provides a method, comprising variably coupling a varactor into a resonator through an RF transformer, wherein by varying a coupling factor, the Q-factor and the tunability of the apparatus is capable of being affected. Accomplishing the variable coupling may be by using either a lumped-element transformer or a coupled line transformer and wherein high coupling gives low Q and high tuning and low coupling gives high Q and low tuning.

### BRIEF DESCRIPTION OF THE DRAWINGS

The present invention is described with reference to the accompanying drawings. In the drawings, like reference numbers indicate identical or functionally similar elements. Additionally, the left-most digit(s) of a reference number identifies the drawing in which the reference number first appears.

FIG. 1 illustrates a lossy capacitor model for a general varactor of one embodiment of the present invention;

FIG. 2 shows a lossy capacitor model for the varactor and fixed capacitor in parallel combination of one embodiment of the present invention;

FIG. 3 illustrates an equivalent transmission line cavity resonator model for a tunable 4-pole bandpass filter of one embodiment of the present invention;

FIG. 4 shows the filter response of the 4-pole tunable filter with low-Q varactors of one embodiment of the present invention;

FIG. 5 shows the equivalent transmission line cavity resonator model for a tunable 4-pole bandpass filter with added fixed capacitors of one embodiment of the present invention;

FIG. 6 shows the filter response for the 4-pole TL cavity filter with the combined low-Q varactors and high-Q fixed capacitors of one embodiment of the present invention; and

FIG. 7 depicts the detailed effect of Q factor of the fixed capacitor and varactor combination on filter performance of one embodiment of the present invention.

### DESCRIPTION OF THE PREFERRED EMBODIMENT

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

Some embodiments of the present invention may generally relates to voltage tunable capacitors (herein referred to as “varactors”) such as and not limited to semiconductor varactors, voltage tunable dielectric capacitors, ferroelectric capacitors, MEMS voltage tunable capacitors Parascan® voltage tunable capacitors, Parascan® variable capacitors, Parascan® tunable dielectric capacitors and Parascan® varactors.

The term Parascan® as used herein is a trademarked term indicating a tunable dielectric material developed by the assignee of the present invention. Parascan® tunable dielectric materials have been described in several patents. Barium strontium titanate (BaTiO3-SrTiO3), also referred to as BSTO, is used for its high dielectric constant (200-6,000) and large change in dielectric constant with applied voltage (25-75 percent with a field of 2 Volts/micron). Tunable dielectric materials including barium strontium titanate are disclosed in U.S. Pat. No. 5,312,790 to Sengupta, et al. entitled “Ceramic Ferroelectric Material”; U.S. Pat. No. 5,427,988 by Sengupta, et al. entitled “Ceramic Ferroelectric Composite Material-BSTO—MgO”; U.S. Pat. No. 5,486,491 to Sengupta, et al. entitled “Ceramic Ferroelectric Composite Material-BSTO—ZrO2”; U.S. Pat. No. 5,635,434 by Sengupta, et al. entitled “Ceramic Ferroelectric Composite Material-BSTO-Magnesium Based Compound”; U.S. Pat. No. 5,830,591 by Sengupta, et al. entitled “Multilayered Ferroelectric Composite Waveguides”; U.S. Pat. No. 5,846,893 by Sengupta, et al. entitled “Thin Film Ferroelectric Composites and Method of Making”; U.S. Pat. No. 5,766,697 by Sengupta, et al. entitled “Method of Making Thin Film Composites”; U.S. Pat. No. 5,693,429 by Sengupta, et al. entitled “Electronically Graded Multilayer Ferroelectric Composites”; U.S. Pat. No. 5,635,433 by Sengupta entitled “Ceramic Ferroelectric Composite Material BSTO—ZnO”; U.S. Pat. No. 6,074,971 by Chiu et al. entitled “Ceramic Ferroelectric Composite Materials with Enhanced Electronic Properties BSTO Mg Based Compound-Rare Earth Oxide”. These patents are incorporated herein by reference. The materials shown in these patents, especially BSTO—MgO composites, show low dielectric loss and high tunability. Tunability is defined as the fractional change in the dielectric constant with applied voltage.

Barium strontium titanate of the formula BaxSr1-xTiO3 is a preferred electronically tunable dielectric material due to its favorable tuning characteristics, low Curie temperatures and low microwave loss properties. In the formula BaxSr1-xTiO3, x can be any value from 0 to 1, preferably from about 0.15 to about 0.6. More preferably, x is from 0.3 to 0.6.

Other electronically tunable dielectric materials may be used partially or entirely in place of barium strontium titanate. An example is BaxCa1-xTiO3, where x is in a range from about 0.2 to about 0.8, preferably from about 0.4 to about 0.6. Additional electronically tunable ferroelectrics include PbxZr1-xTiO3 (PZT) where x ranges from about 0.0 to about 1.0, PbxZr1-xSrTiO3 where x ranges from about 0.05 to about 0.4, KtaxNb1-xO3 where x ranges from about 0.0 to about 1.0, lead lanthanum zirconium titanate (PLZT), PbTiO3, BaCaZrTiO3, NaNO3, KNbO3, LiNbO3, LiTaO3, PbNb206, PbTa206, KSr(NbO3) and NaBa2(NbO3)5KH2PO4, and mixtures and compositions thereof. Also, these materials can be combined with low loss dielectric materials, such as magnesium oxide (MgO), aluminum oxide (Al2O3), and zirconium oxide (ZrO2), and/or with additional doping elements, such as manganese (MN), iron (Fe), and tungsten (W), or with other alkali earth metal oxides (i.e. calcium oxide, etc.), transition metal oxides, silicates, niobates, tantalates, aluminates, zirconnates, and titanates to further reduce the dielectric loss.

In addition, the following U.S. Patent Applications, assigned to the assignee of this application, disclose additional examples of tunable dielectric materials: U.S. application Ser. No. 09/594,837 filed Jun. 15, 2000, entitled “Electronically Tunable Ceramic Materials Including Tunable Dielectric and Metal Silicate Phases”; U.S. application Ser. No. 09/768,690 filed Jan. 24, 2001, entitled “Electronically Tunable, Low-Loss Ceramic Materials Including a Tunable Dielectric Phase and Multiple Metal Oxide Phases”; U.S. application Ser. No. 09/882,605 filed Jun. 15, 2001, entitled “Electronically Tunable Dielectric Composite Thick Films And Methods Of Making Same”; U.S. application Ser. No. 09/834,327 filed Apr. 13, 2001, entitled “Strain-Relieved Tunable Dielectric Thin Films”; and U.S. Provisional Application Ser. No. 60/295,046 filed Jun. 1, 2001 entitled “Tunable Dielectric Compositions Including Low Loss Glass Frits”. These patent applications are incorporated herein by reference.

The tunable dielectric materials can also be combined with one or more non-tunable dielectric materials. The non-tunable phase(s) may include MgO, MgAl2O4, MgTiO3, Mg2SiO4, CaSiO3, MgSrZrTiO6, CaTiO3, Al2O3, SiO2 and/or other metal silicates such as BaSiO3 and SrSiO3. The non-tunable dielectric phases may be any combination of the above, e.g., MgO combined with MgTiO3, MgO combined with MgSrZrTiO6, MgO combined with Mg2SiO4, MgO combined with Mg2SiO4, Mg2SiO4 combined with CaTiO3 and the like.

Additional minor additives in amounts of from about 0.1 to about 5 weight percent can be added to the composites to additionally improve the electronic properties of the films. These minor additives include oxides such as zirconnates, tannates, rare earths, niobates and tantalates. For example, the minor additives may include CaZrO3, BaZrO3, SrZrO3, BaSnO3, CaSnO3, MgSnO3, Bi2O3/2SnO2, Nd2O3, Pr7O11, Yb2O3, Ho2O3, La2O3, MgNb2O6, SrNb2O6, BaNb2O6, MgTa2O6, BaTa2O6 and Ta2O3.

Thick films of tunable dielectric composites may comprise Ba1-xSrxTiO3, where x is from 0.3 to 0.7 in combination with at least one non-tunable dielectric phase selected from MgO, MgTiO3, MgZrO3, MgSrZrTiO6, Mg2SiO4, CaSiO3, MgA1204, CaTiO3, Al2O3, SiO2, BaSiO3 and SrSiO3. These compositions can be BSTO and one of these components, or two or more of these components in quantities from 0.25 weight percent to 80 weight percent with BSTO weight ratios of 99.75 weight percent to 20 weight percent.

The electronically tunable materials may also include at least one metal silicate phase. The metal silicates may include metals from Group 2A of the Periodic Table, i.e., Be, Mg, Ca, Sr, Ba and Ra, preferably Mg, Ca, Sr and Ba. Preferred metal silicates include Mg2SiO4, CaSiO3, BaSiO3 and SrSiO3. In addition to Group 2A metals, the present metal silicates may include metals from Group 1A, i.e., Li, Na, K, Rb, Cs and Fr, preferably Li, Na and K. For example, such metal silicates may include sodium silicates such as Na2SiO3 and NaSiO3-5H₂O, and lithium-containing silicates such as LiAlSiO4, Li2SiO3 and Li4SiO4. Metals from Groups 3A, 4A and some transition metals of the Periodic Table may also be suitable constituents of the metal silicate phase. Additional metal silicates may include Al2Si2O7, ZrSiO4, KalSi3O8, NaAlSi3O8, CaAl2Si2O8, CaMgSi2O6, BaTiSi3O9 and Zn2SiO4. The above tunable materials can be tuned at room temperature by controlling an electric field that is applied across the materials.

In addition to the electronically tunable dielectric phase, the electronically tunable materials can include at least two additional metal oxide phases. The additional metal oxides may include metals from Group 2A of the Periodic Table, i.e., Mg, Ca, Sr, Ba, Be and Ra, preferably Mg, Ca, Sr and Ba. The additional metal oxides may also include metals from Group 1A, i.e., Li, Na, K, Rb, Cs and Fr, preferably Li, Na and K. Metals from other Groups of the Periodic Table may also be suitable constituents of the metal oxide phases. For example, refractory metals such as Ti, V, Cr, Mn, Zr, Nb, Mo, Hf, Ta and W may be used. Furthermore, metals such as Al, Si, Sn, Pb and Bi may be used. In addition, the metal oxide phases may comprise rare earth metals such as Sc, Y, La, Ce, Pr, Nd and the like.

The additional metal oxides may include, for example, zirconnates, silicates, titanates, aluminates, stannates, niobates, tantalates and rare earth oxides. Preferred additional metal oxides include Mg2SiO4, MgO, CaTiO3, MgZrSrTiO6, MgTiO3, MgAl2O4, WO3, SnTiO4, ZrTiO4, CaSiO3, CaSnO3, CaWO4, CaZrO3, MgTa206, MgZrO3, MnO2, PbO, Bi203 and La2O3. Particularly preferred additional metal oxides include Mg2SiO4, MgO, CaTiO3, MgZrSrTiO6, MgTiO3, MgAl2O4, MgTa2O6 and MgZrO3.

The additional metal oxide phases are typically present in total amounts of from about 1 to about 80 weight percent of the material, preferably from about 3 to about 65 weight percent, and more preferably from about 5 to about 60 weight percent. In one preferred embodiment, the additional metal oxides comprise from about 10 to about 50 total weight percent of the material. The individual amount of each additional metal oxide may be adjusted to provide the desired properties. Where two additional metal oxides are used, their weight ratios may vary, for example, from about 1:100 to about 100:1, typically from about 1:10 to about 10:1 or from about 1:5 to about 5:1. Although metal oxides in total amounts of from 1 to 80 weight percent are typically used, smaller additive amounts of from 0.01 to 1 weight percent may be used for some applications.

The additional metal oxide phases can include at least two Mg-containing compounds. In addition to the multiple Mg-containing compounds, the material may optionally include Mg-free compounds, for example, oxides of metals selected from Si, Ca, Zr, Ti, Al and/or rare earths.

Quality factor (or Q) of a resonant circuit is proportional to the ratio of the average stored energy over the energy loss in the circuit. Thus it is a measure of the loss of a resonant circuit and lower loss implies higher Q. RF components with high Q are always desired in the design of radio devices and systems for RF, microwave and millimeter wave applications. For example, high-Q resonator or lumped-element components are desired to build high-Q filters, which capably possess preferable filter performance such as superior insertion loss and stop-band rejections. Tunable filters have been developed for radio frequency applications. They may be tuned electronically by using either dielectric varactors or microelectro-mechanical systems (MEMS) technology based varactors. In these tunable filters, high-Q varactors are essential to achieve improved filter design and performance.

An embodiment of the present invention provides apparatus and methods to improve the quality factor of voltage tunable capacitors (herein referred to as “varactors”). Some embodiments of the present invention provide for use in voltage tunable dielectric capacitors using tunable RF bandpass filters as well as other RF, microwave and millimeter wave circuits such as voltage controlled oscillators and phase shifters in phased array antennas incorporating one or more voltage tunable capacitors. It is understood that the present invention is not limited to these enumerated uses as these embodiments are merely illustrative and used for purposes of enabling one of ordinary skill in the art to practice the invention.

A tunable dielectric capacitor used in the present invention may be made from low loss tunable dielectric film. Although not limited in this respect, the range of Q-factor of the tunable dielectric capacitor may between 50, for very high tuning material, and 300, for low tuning materials. It may decrease with the increase of the frequency, but even at higher frequencies, say 30 GHz, may have values as high as 100. A wide range of capacitance of the tunable dielectric capacitors is available; for example 0.1 pF to several nF. The tunable dielectric capacitor may be packaged in a two-port component, in which the tunable dielectric may be voltage-controlled, although the present invention is not limited to this packaging. The tunable film may be deposited on a substrate, such as MgO, LaAlO3, sapphire, Al2O3 and other dielectric substrates. An applied voltage may produce an electric field across the tunable dielectric, which produces an overall change in the capacitance of the tunable dielectric capacitor.

An embodiment of the present invention provides methods of improving varactor Q using the combination of external high-Q fixed capacitors with the desired varactors, and internal low-tuning high-Q material for building varactors with high-Q and large capacitance but low tuning range, or the combination of both of these methods.

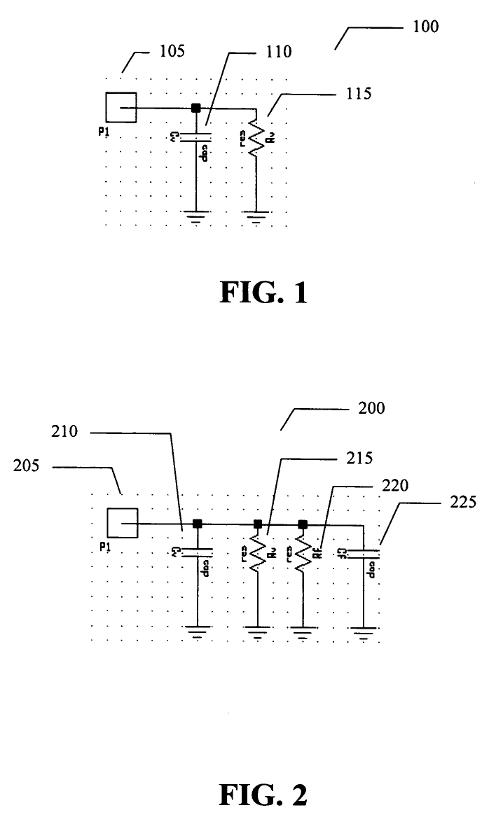

Generally, the quality factor (O) of a capacitor or varactor can be interpreted as the parallel model as shown generally as 100 in FIG. 1 where Q is written as

At the expense of capacitance tuning, the quality factor of the capacitive component may be improved by adding a high Q fixed capacitor 110 or lowering tuning with high Q tunable materials, or both. In FIG. 1 input is illustrated at 105 with resister at 115.

Turning now to FIG. 2, generally at 200, is an example, with a fixed capacitor with capacitance of C_{f} (225)=aCᵥ (210) and Q_{f}=kQᵥ (thus R_{f} (220)=kRᵥ (215)) is added in parallel with a lower Q varactor, Cᵥ (210). Input is illustrated at 205. Now Q of this capacitive combination can be expressed as

$$Q = ω RC = ω \frac{k}{k + 1} {R}_{v} ( a + 1 ) {C}_{v} = \frac{k}{k + 1} ( a + 1 ) {Q}_{v} \qquad ( 2 )$$

In terms of design computation, the following equations guide the selection of the high-Q part of varactor or the fixed capacitor in the capacitive combination. When the design targets are determined (Q_{design} and C_{design}), the combination of these low-Q parts and high-Q parts only depends on the availability of the other four properties, i.e. Qᵥ, Cᵥ, Q_{f} and C_{f}.

$$\frac{{Q}_{design}}{{Q}_{v}} = \frac{{Q}_{f}}{{Q}_{f} + {Q}_{v}} ( \frac{{C}_{f}}{{C}_{v}} + 1 ) \qquad ( 3 )$$

C_{design}=Cᵥ+C_{f} (4)

The embodiment of a high-Q capacitive composition may be equally applicable to a series combination of a high-Q fixed capacitor and a varactor. In this case, the following equations (5) and (6) will govern the embodiment design. Both of the parallel and the series combinations have the same effect on the overall Q-factor and tunability, however, the total capacitance of the composition varies in opposite direction from the varactor itself. In the parallel case, the overall capacitance is increased while it is lowered in the series case.

$$\begin{matrix}\frac{{Q}_{design}}{{Q}_{v}} = \frac{{C}_{f}}{{C}_{f} + {C}_{v}} ( \frac{{Q}_{f}}{{Q}_{v}} + 1 ) & ( 5 ) \\ \frac{{C}_{design}}{Cv} = \frac{{C}_{f}}{{C}_{v} + {C}_{f}} & ( 6 )\end{matrix}$$

In addition, the embodiment of a high-Q capacitive combination can be formed as a varactor coupled into the resonator through some RF transformer, either a lumped-element transformer or a coupled line transformer. By varying the coupling factor, the Q-factor and the tunability is affected: high (tight) coupling gives low Q and high tuning, low (loose) coupling gives high Q and low tuning.

In all the embodiments aforementioned, the trade-off is to achieve the varactor Q improvement at the expense of its capacitance tuning. Meanwhile, the varactor intermodulation distortion has also been mitigated, thus its third-order intermodulation product, i.e. IP3 is improved.

As an example of the Q improvement techniques of some embodiments of the present invention, a 4-pole bandpass filter may be employed to demonstrate the effect of Q improvement on the circuit performance. Similar improvement on the performance from Q factor can be expected on other circuits such as amplifiers, voltage controlled oscillators and phase shifters.

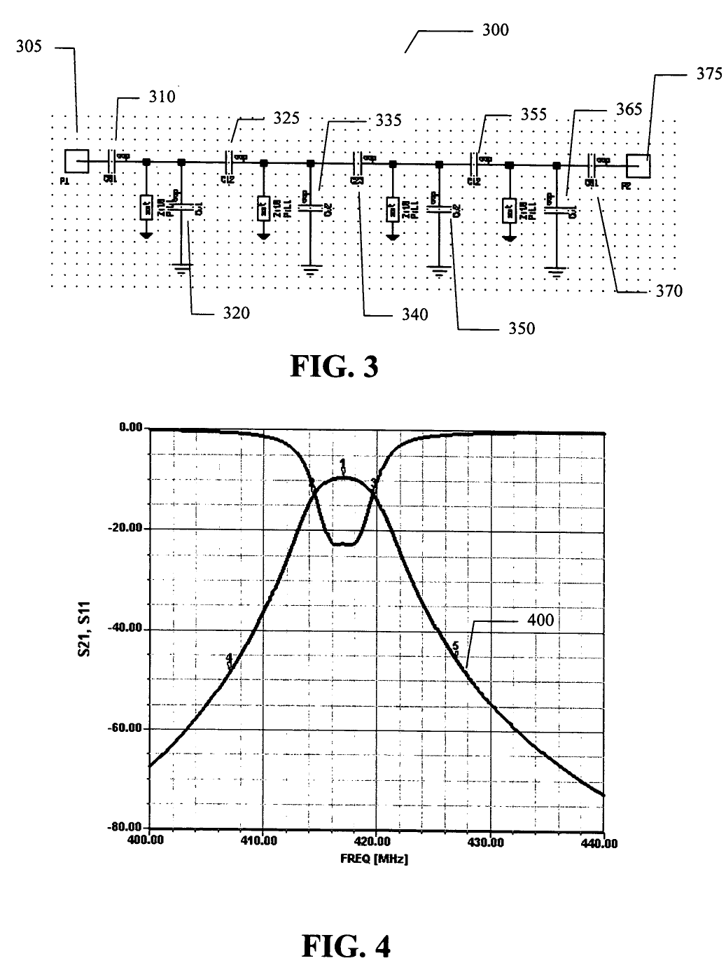

Turning now to FIG. 3, illustrated generally as 300, is a basic resonator with input 305 and output 375 that is represented by a transmission line cavity structure with capacitors 310, 325, 340, 355 and 370 which is made tunable by adding tunable capacitors 320, 335, 350, and 365. Typical filter response of this 4-pole tunable filter with low-Q varactors is shown in FIG. 4 at 400.

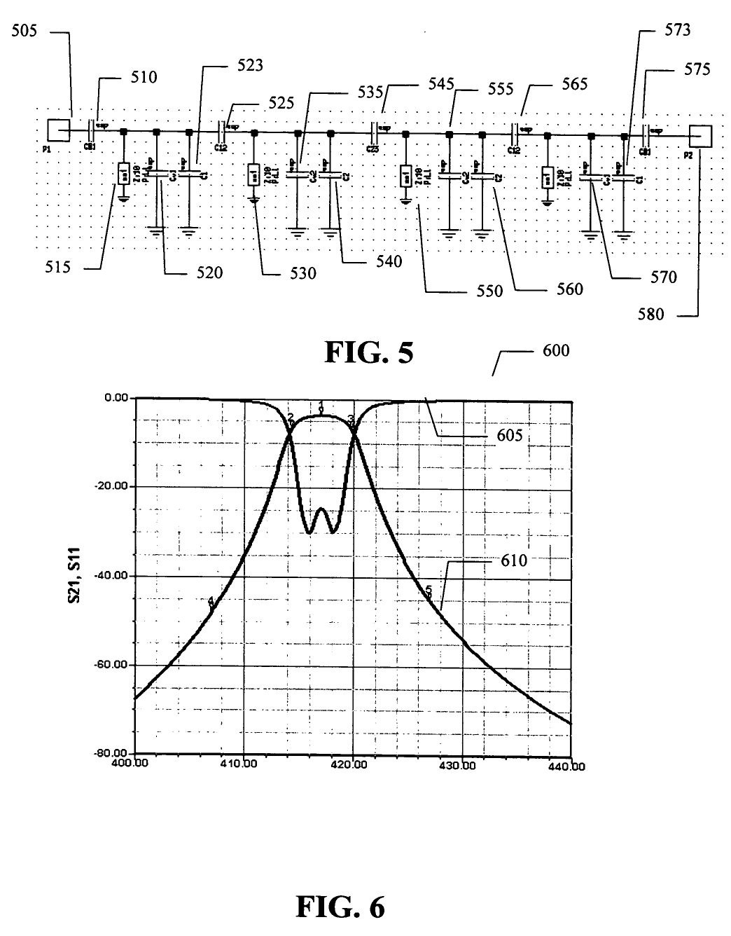

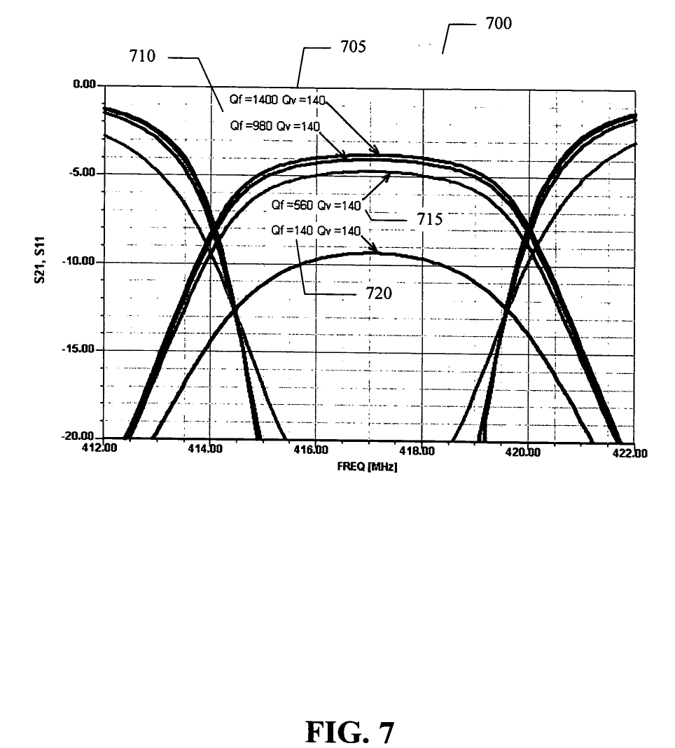

In an embodiment of the present invention, as illustrated in FIG. 5, to improve the capacitive part Q factor of a basic resonator with input 505 and output 580 and capacitors 510, 523 545 and 565, fixed capacitors 523, 540, 560 and 573 are added in parallel with the varactors 520, 535, 555 and 570 based on the desired values determined from equations (3) and (4). The improvement of filter response is shown in FIG. 6 at 600. FIG. 7, generally at 700, graphically illustrates the detailed effect of Q factor of the fixed capacitor and varactor combinations 705, 710, 715 and 720 on filter performance.

While the present invention has been described in terms of what are at present believed to be its preferred embodiments, those skilled in the art will recognize that various modifications to the disclose embodiments can be made without departing from the scope of the invention as defined by the following claims.

What is claimed is:

1. An apparatus, comprising:
a varactor; and
at least one external high-Q fixed capacitor combined with said varactor thereby improving the Q of said varactor.

2. The apparatus of claim 1, wherein said at least one external high-Q fixed capacitor is combined in series with said varactor.

3. The apparatus of claim 1, wherein said at least one external high-Q fixed capacitor is combined in parallel with said varactor.

4. The apparatus of claim 1, wherein said varactor is constructed of an internal low-tuning high-Q material with high-Q and large capacitance but low tuning range.

5. The apparatus of claim 1, wherein said apparatus is incorporated into a 4-pole bandpass filter enabling Q improvement in said filter.

6. The apparatus of claim 1, wherein said apparatus is incorporated into an amplifier or a voltage controlled oscillator or a phase shifter.

7. An apparatus, comprising:
a resonator; and
a varactor variably coupled into said resonator through an RF transformer, wherein by varying a coupling factor, the Q-factor and the tunability of said apparatus is capable of being affected.

8. The apparatus of claim 5, wherein said variable coupling is accomplished by either a lumped-element transformer or a coupled line transformer.

9. The apparatus of claim 5, wherein high coupling gives low Q and high tuning and low coupling gives high Q and low tuning.

10. A method of improving the Q of a varactor, comprising:
combining at least one external high-Q fixed capacitor with said varactor thereby improving the Q of said varactor.

11. The method of claim 10, further comprising combining said at least one external high-Q fixed capacitor in series with said varactor.

12. The method of claim 10, further comprising combining said at least one external high-Q fixed capacitor in parallel with said varactor.

13. The method of claim 10, further comprising constructing said varactors of an internal low-tuning high-Q material with high-Q and large capacitance but low tuning range.

14. The method of claim 10, further comprising incorporating said at least one external high-Q fixed capacitor with said varactor into a 4-pole bandpass filter enabling Q improvement.

15. The method of claim 10, further comprising incorporating said at least one external high-Q fixed capacitor with said varactor into an amplifier or a voltage controlled oscillators or a phase shifters.

16. A method, comprising:
variably coupling a varactor into a resonator through an RF transformer, wherein by varying a coupling factor, the Q-factor and the tunability of said apparatus is capable of being affected.

17. The method of claim 16, further comprising accomplishing said variable coupling by using either a lumped-element transformer or a coupled line transformer.

18. The method of claim 16, wherein high coupling gives low Q and high tuning and low coupling gives high Q and low tuning.

19. The apparatus of claim 1, wherein whether or not said at least one external high-Q fixed capacitor is combined in series with said varactor or in parallel with said varactor both have the same effect on the overall Q-factor and tunability.

20. The apparatus of claim 1, wherein an overall capacitance of said apparatus is increased if said at least one external high-Q fixed capacitor is combined in parallel with said varactor and lowered if said at least one external high-Q fixed capacitor is combined in series with said varactor.
